(19) United States
(12) Patent Application Publication
(10) Pub. No.: US 2006/0068450 A1
(43) Pub. Date: Mar. 30, 2006

(54) Microbead-filled microsystem and production method thereof

(75) Inventors: Philippe Combette, Montpellier (FR); Frederique Mittler, St Egreve (FR); Patrice Caillat, Echirolles (FR)

Correspondence Address: OBLON, SPIVAK, MCCLELLAND, MAIER & NEUSTADT, P.C., 1940 DUKE STREET, ALEXANDRIA, VA, 22314, US

(73) Assignee: Commissaraiat A L'Energie Atomique Atomique, Paris (FR)

(21) Appl. No.: 10/533,947

(22) PCT Filed: Nov. 12, 2003
(86) PCT No.: PCT/FR03/50117

§ 371 Date: May 4, 2005

(30) Foreign Application Priority Data
Nov. 13, 2002 (FR) 02/14177

(51) Int. Cl. G01N 33/542; C12M 1/34; G01N 33/53

(52) U.S. Cl. 435/7.9; 435/287.2

(57) ABSTRACT

The invention relates to a micro-system intended to receive beads and to obtain a precise positioning of the beads at preset locations in the micro-system. This micro-system comprises a tank that has a cavity, the cavity being fitted with blocking elements allowing the beads to be ordered and stacked in the interstices between the blocking elements, the interstices constituting the preset locations. It also comprises a cap anchored hermetically to the tank and input means and output means allowing a fluid to flow in the cavity. The invention also relates to the implementation and use of the bead-filled micro-system.

### TECHNICAL FIELD

The present invention relates to a micro-system intended to receive beads of defined diameter.

The invention also relates to a process for the making and a process for the filling of such a micro-system in order to obtain a micro-reactor.

The invention relates lastly to a process for implementing a biochemical or biological reaction making use of said bead-filled micro-system.

The field of the invention may be defined as that of miniaturised systems or micro-systems which are used essentially for chemical analysis and synthesis.

The incorporation of beads into a micro-system is widely used in the context of analysis or biochemical reactions: the use of these pre-functionalised beads, the diameter of which is between about ten nanometers up to about a hundred micrometers, allows chemical functions to be obtained without passing through stages of functionalising the different components of a micro-system.

These beads are also used in chromatographic separation systems in respect of which they are stacked in capillary tubes of different diameters.

Several other applications show the use of beads in micro-systems (devices then known by the term of “micro-reactors”), particularly for the pre-concentration of proteins, for reactions that depend on antigen-antibody recognitions. Their applications may also be extended to the field of chemistry.

### PRIOR ART

Examples of micro-systems that use these beads are more clearly described in the following documents.

In the document [1] cited at the end of the present description, the authors present a micro-system dedicated to a chromatographic separation: two barriers delimit a cavity and allow the capture of beads that have on their surface a hydrophobic phase of the octadecylsilane type. The beads are introduced into the cavity by electro-osmosis.

A difference in dimension between the depth of the cavity and the height of the barriers causes the beads with a diameter above this value to be blocked. In this device, once the beads are introduced into the cavity, they can theoretically be removed from it by using a flow which is the reverse of the one used when introducing them, either by electro-osmosis, or by a conventional pump. However, after use, extracting the beads from the cavity is complex. Furthermore, although the filling is homogeneous, the different images of the cavity during the filling show areas where there are heterogeneities.

In the document [2] cited at the end of the present description, the authors use a quasi-identical device to bring about an enzymatic reaction, followed by an analysis of the products arising from this reaction. This time, beads of a diameter of between 40 and 60 micrometers are introduced into a cavity using a conventional pump. In this case, given the different diameters of the beads, stacking them within the cavity produces heterogeneities.

In the document [3] cited at the end of the present description, the authors present another system that allows micro-spheres to be blocked. A reaction chamber is composed of bars made when the device is made and with the spacing between them smaller than the diameter of the beads to be blocked. Once again, the beads are introduced once the system is closed. The solution offered by this set of bars does not allow, as in the previous devices, the filling to be guaranteed free from heterogeneities. In this case, the arrangement of the chamber trapping the beads allows them to be better extracted from it by using a liquid flow that is contrary to that used for the filling. However, it may be feared with this system that general bead clusters will block the channels and prevent the chamber either from being filled, or from being emptied. Moreover, there is nothing to ensure constant spacing between the beads throughout the micro-system.

The authors of the document [4], cited at the end of the present description, present a method for assembling, locally, different types of micro-beads. The principle is based on the generation of a matrix of discs separated from each other by a hydrophobic surface. The surface of each one of these discs is then chemically modified by a “micro-contact printing” type deposition which uses a matrix previously impregnated with the products to be deposited. The chip fitted with these discs having reactive groups is then soaked in a solution containing micro-spheres in solution. These micro-spheres will be adsorbed on the surface of the discs with an affinity characteristic of the nature of the reactive groups present on the surface of the micro-spheres and on the surface of the discs. But in this case, given the embodiment of the device, only a single layer of beads can be obtained in the micro-system.

The works previously cited highlight the advantages of these micro-beads, both with regard to the ease of use and to the huge choice of biochemical functions that they are able to offer. However, these devices still have drawbacks, particularly the operation of filling the micro-systems using functionalised beads which remains a tricky operation. With regard to this point in particular, it is important to note that the micro-beads can only be incorporated in the previously cited devices after the tanks have been closed with a cap. This supposes particularly that the implemented system can block the beads at a precise location, but also that both the bead carrying fluid and the associated pumping device are managed. These stages could be greatly simplified if it were possible to introduce the beads into the tanks before they were closed. In this event, filling the tanks with micro-beads would be much easier since accessibility would be greatly increased. In parallel with this filling mode, a tank geometry should be defined such that it is able to act as a micro-sieve and ensure the micro-beads are evenly stacked and precisely positioned. Once the micro-beads are fitted in the tank, the latter might be sealed by closure with a cap. Furthermore, if it is wished to insert beads of different functions, it would be advantageous to be able to place these beads at preset locations and thus to control the locations where the chemical reactions are to take place.

It transpires from what has been said above that there is a need for a micro-system which could be easily filled with micro-beads and also allow said beads to be positioned within the micro-system in a precise and reproducible way.

### DISCLOSURE OF THE INVENTION

The purpose of the present invention is to provide a micro-system which meets, inter alia, these needs.

This purpose and others besides are achieved, in accordance with the invention, by a micro-system intended to receive beads and to obtain a precise positioning of said beads at preset locations in the micro-system, characterised in that it comprises a tank that has a cavity, said cavity being fitted with blocking elements that allow the beads to be ordered and stacked in the interstices between the blocking elements, the interstices constituting said preset locations, a cap hermetically sealing the cavity and import means and output means allowing a fluid to flow in the cavity.

Advantageously, the blocking elements of said micro-system may consist of columns that are integral with the bottom of the cavity or the cap. The material for the beads may be selected, depending on the application, from among mineral materials, metals, or organic compounds depending on the function they are to fulfil.

If said micro-system is intended to receive beads that all have the same diameter, the blocking elements may be evenly placed in a two-dimensional network. In this case, the network for arranging the blocking elements in the cavity is chosen as a function of the ratio of volume of beads to surface available that is wished to obtain in the micro-system, and of the diameter of the beads to be inserted therein. The beads placed in one and the same interstice are of the same diameter.

According to a first embodiment, the two-dimensional network may be a hexagonal mesh.

According to a second embodiment, the two-dimensional network may be a square mesh.

If said micro-system is intended to receive beads of different diameters, the blocking elements will be distributed so as to obtain a positioning of the beads as a function of their diameters.

According to one particular embodiment of the invention, the blocking elements will be distributed so as to constitute wells intended to receive beads of a first preset diameter and spaces between the wells intended to receive beads of a second preset diameter.

Whatever the embodiments, the blocking elements of the micro-system according to the invention will have a transverse cross-section of any shape. However, advantageously, their cross-sections will have a shape selected from among discs, ellipses and polygons.

According to one particular embodiment the blocking elements will have a transverse cross-section in the shape of a hexagon.

Advantageously, the blocking elements will be of a height that allows at least two beads to be stacked.

Another subject of the invention concerns a micro-reactor.

According to a first embodiment, said micro-reactor may include a micro-system filled with beads of one and the same diameter and identically functionalised, fitted between the blocking elements.

According to another embodiment, said micro-reactor will include a micro-system filled with beads of the same diameter but functionalised differently, said beads being fitted between the blocking elements, the ratio between the quantities of beads fulfilling different functions being selected as a function of the required effect.

According to another embodiment, said micro-reactor will include a micro-system filled with beads of different diameters, each diameter corresponding to a different functionalisation, said beads being fitted between the blocking elements; in this latter embodiment, beads of one and the same diameter constitute localised functionalised areas. By “functionalised beads”, should be understood “beads fulfilling one function or several different functions”.

The purpose of the invention is also to provide a process for making a micro-system according to the invention, said process comprising the following stages:

forming, by micro-machining a substrate, the tank that has the cavity fitted with the blocking elements,

supplying a cap intended to seal the tank cavity hermetically,

forming the fluid import means and output means by micro-machining the tank and/or cap.

According to one embodiment, said micro-machining will be carried out by a process of dry or wet etching a material.

According to another embodiment, said micro-machining will be carried out by an impression moulding process.

According to another embodiment, said micro-machining will be carried out by photolithography process.

Another subject of the invention relates to processes for obtaining various micro-reactors.

First of all, a process for obtaining a micro-reactor that includes a micro-system filled with beads of one and the same diameter and with the same function, said process comprising a stage of sedimentation filling with functionalised beads in suspension in a liquid.

In other words, the process includes the following stages:

placing the micro-system tank at the bottom of a container,

introducing into the container a solution containing the functionalised beads in suspension and filling the cavity interstices by sedimentation of the beads,

sealing the tank with the cap.

The invention also relates to a process for obtaining a multi-functional micro-reactor by filling a micro-system with functionalised beads of one and the same diameter but with different functions, said process including:

for the functionalised beads according to a first function, the following stages:

a) placing a cover on the micro-system tank leaving accessible the part in which it is wished to place the beads of a first function,

b) filling by sedimentation,

c) withdrawing the cover,

for beads functionalised according to another function, the repetition, as many times as there are functions remaining, of stages a) to c) with beads of said other function,

sealing the tank with the cap.

Finally, the process for obtaining a multi-functional micro-reactor by filling the micro-system with beads the function of which is related to the diameter of said beads, said process including at least two filling stages, the order of the filling stages corresponding to the decreasing order of the diameter of the beads.

In other words, said process includes:

for beads of greater diameter, the following stages:

a) placing the micro-system tank at the bottom of a container,

b) introducing into the container a solution containing the beads and filling the cavity interstices by sedimentation of the beads,

for beads of smaller diameter, the repetition, as many times as necessary and in decreasing order of diameter, of stages a) to b),

sealing the tank with the cap.

A micro-system for filling with functionalised beads designed in accordance with the invention has a certain number of advantages.

The device allows a very considerable reaction surface to be developed with additionally a three-dimensional geometry.

Moreover, the micro-system according to the invention and its filling mode, since it allows the beads to be stacked and precisely positioned within the micro-system, also allows to obtain a multi-functionalisation in volume by depositions of micro-beads having different functions. Indeed, as can be seen previously, micro-beads of different natures can be incorporated in one and the same device.

Furthermore, by guaranteeing a controlled inter-bead space throughout the micro-system there is no further risk of bead aggregates causing a blockage in the micro-system.

This device also allows an easy filling stage.

Likewise, expelling the micro-beads is facilitated. Indeed, if the reactor is not definitively sealed, the cap may be removed. In this case, passing the micro-reactor through a rinsing solution coupled with ultrasound agitation allows the micro-beads to be expelled from their housing. To obtain a usable device once again, all there is to do is to recommence the filling operation. This process then makes it possible, either to reactivate the function offered by the beads which may deteriorate over time, or to change the function embodied by the micro-reactor while retaining its geometry.

Furthermore, the invention also relates to a process for implementing a chemical, electrochemical, biochemical or biological reaction wherein a fluid stream is made to flow in a micro-reactor according to the invention, so that at least one constituent of said fluid stream reacts with the pre-functionalised beads able to produce a chemical, electrochemical, biological or biochemical reaction, and at the micro-reactor output(s) a fluid stream is collected that includes the product(s) of said reaction.

According to one preferred embodiment of the invention, said reaction is a reaction of the substrate enzyme type and said pre-functionalised beads able to produce a biological or biochemical reaction are enzymes, said constituent of the fluid stream is a substrate of the enzyme and the products of the reaction are the products arising from the reaction of said enzyme with said substrate.

According to another embodiment of the invention, said reaction is an enzymatic digestion reaction by a protease, said pre-functionalised beads able to produce a biological or biochemical reaction are proteases and said constituents of the fluid stream are peptides or proteins and the products of the reaction are peptidic segments.

Advantageously, said enzyme is trypsin.

These embodiments of the invention illustrate applications in the biological field, but many other applications may be involved in the fields of chemistry (for example fine chemistry), electrochemistry and biochemistry, in particular in all situations where reactions require the use of rare and/or expensive reagents in order to have to bring into play only small quantities of reagents.

### BRIEF DESCRIPTION OF THE DRAWINGS

The invention will be better understood and other advantages and particularities will emerge from reading the following description, given by way of a non-restrictive example, accompanied by the appended drawings among which:

FIG. 1 is a perspective view from above of the micro-system,

FIG. 2 is a partial view from above of the micro-system in FIG. 1 filled with beads and showing one of the possible arrangements of the blocking elements and of said beads,

FIG. 3 is a cross-section of FIG. 2 along the axis III-III,

FIGS. 4, 5 and 6 are partial views from above of the bead-filled micro-system showing different possible arrangements of the blocking elements and of said beads,

FIGS. 7A to 7F show the making by dry etching process of a micro-system according to the invention.

### DETAILED DESCRIPTION OF EMBODIMENTS OF THE INVENTION

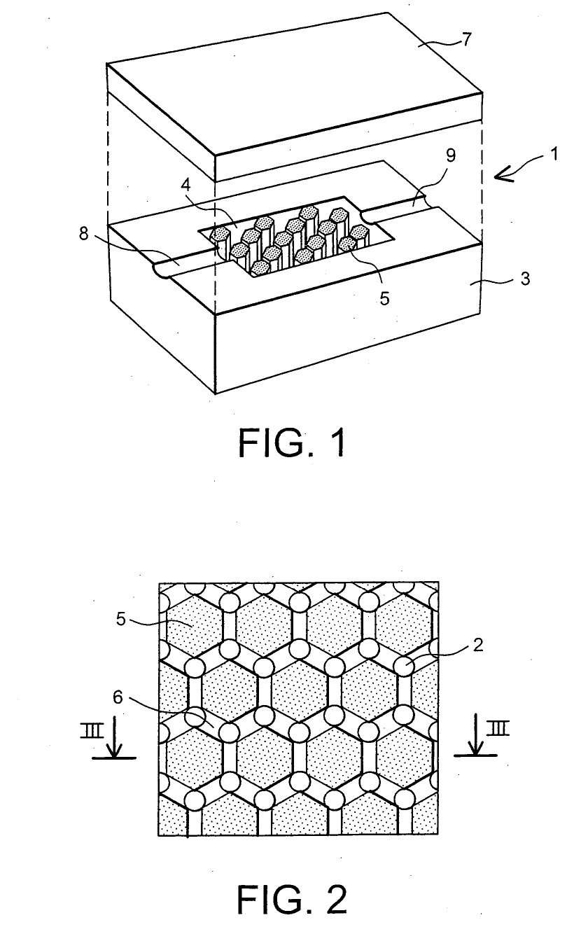

With reference to FIG. 1, the micro-system 1, intended to receive beads, can be seen according to the invention and which comprises:

a tank 3 having a cavity 4, said cavity 4 being fitted with blocking elements 5 allowing the beads to be ordered and stacked in the interstices between the blocking elements 5,

a cap 7 anchored hermetically to the tank 3,

and an import means 8 and an output means 9 allowing the fluid to flow in the cavity.

Depending on the way in which the blocking elements are to be distributed in the tank, the same density of beads will not be present. It is the spatial arrangement and the height of the blocking elements which will define respectively the accessibility surface and the volume to be occupied by the beads.

In one particular embodiment in which it is wished to insert beads of one and the same diameter, the blocking elements are evenly placed in a particular two-dimensional network. In this way, from an arrangement of hexagonal columns placed in a hexagonal mesh, the micro-beads 2 are stacked in the interstices 6 between the columns 5 as shown in FIG. 2. In this figure it can be seen that the beads 2 are positioned in the parts of the interstices 6 delimited by the edges of three adjacent columns.

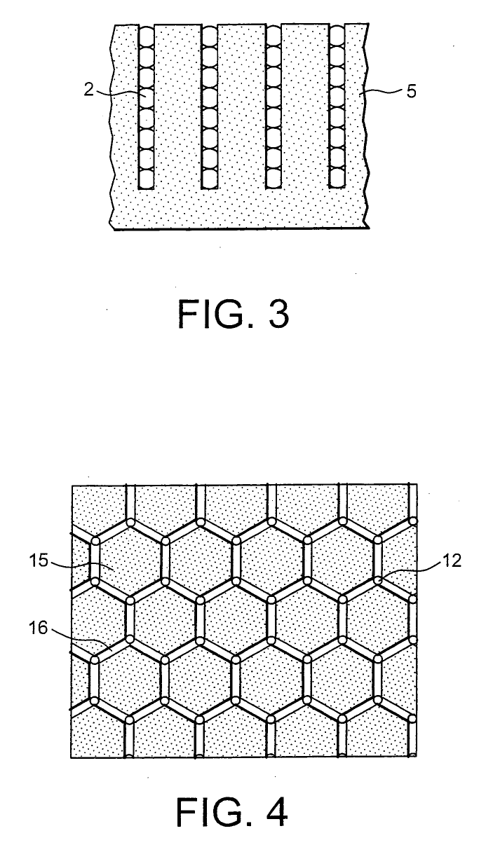

The cross-section view in FIG. 2 along the axis III-III (FIG. 3) gives a good view of the stacking of the micro-beads 2 between the columns 5.

In FIG. 4, the columns 15 are also placed in a hexagonal mesh but the gap between them has been deliberately chosen to be smaller: only beads 12 of smaller diameters than the beads in FIGS. 2 or 3 can be inserted into the interstices 16.

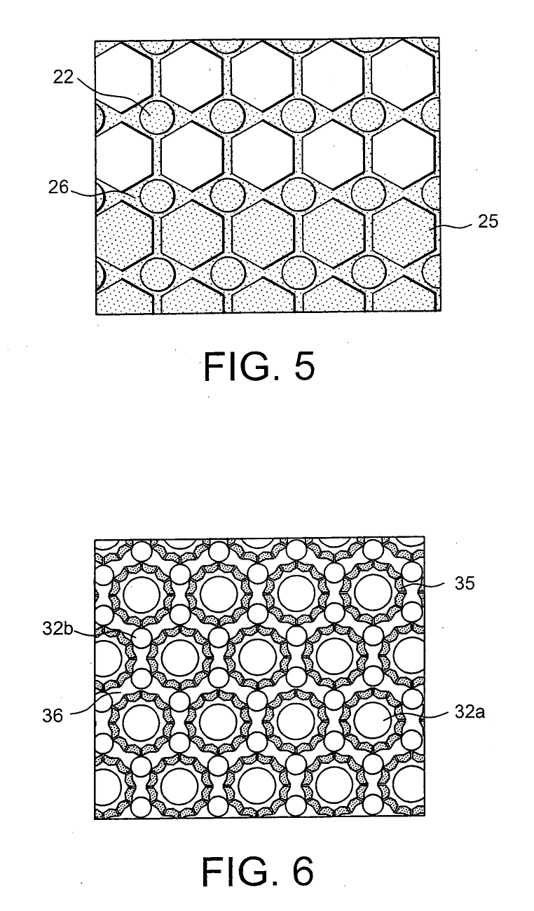

By the same reasoning, several types of matrixing are conceivable if the spatial arrangement of the columns can be modified. Thus, by placing the columns 25, of hexagonal cross-section, in a square network, the arrangement described in FIG. 5 is obtained: beads 22 of a preset diameter are introduced into the parts of the interstices 26 delimited by the surfaces of four adjacent columns.

Beads of different diameters can also be introduced into the micro-system. In FIG. 6, the blocking elements 35 are distributed so as to constitute wells intended to receive the beads of large diameter 32a and the beads of small diameter 32b will be housed in the spaces 36 between the wells. It can be seen that, in this case, it is not the blocking elements in themselves, but rather a set of blocking elements (the wells) that are distributed in a particular two-dimensional network, which is here hexagonal. These wells may also consist of hollow columns the casing of which replaces the blocking elements 35.

During the making of the micro-reactor, two stages may be distinguished:

the first stage consists in making the micro-system per se, in other words arranging the set of elements being used to block the beads within the tank,

the second stage is related to the implantation of said beads between said blocking elements.

The first stage, in other words the stage of micro-machining the micro-system, can be obtained in several different ways: either by dry or wet etching a material, or by moulding an impression, or by photolithography.

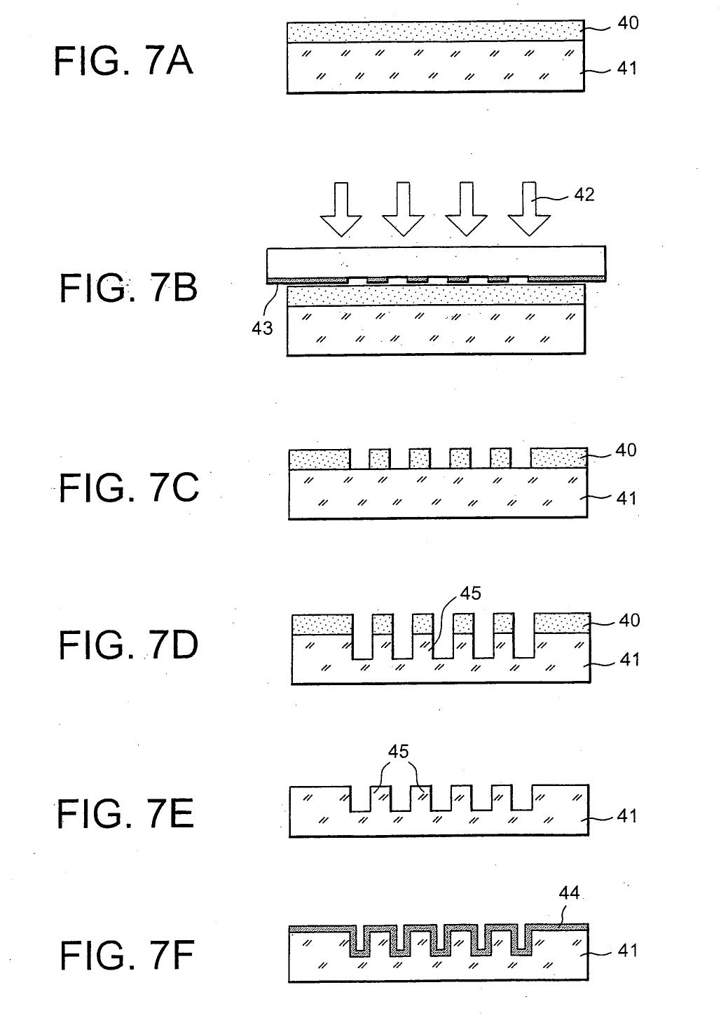

As a non-restrictive example showing a method of micro-machining, it has been decided to clarify the making of a silicon micro-reactor by dry etching, with reference to FIGS. 7A to 7F appended. But other materials can be used: for example, glass, silica, resins, polymers, or even metals. The choice of material will depend on the application.

First of all, a layer of positive photo-sensitive resin 40 is deposited on to a 4 inch (i.e. 10.16 cm) silicon substrate 41 of the <100> type and with a thickness of 525 μm by “spin-coating” and by using as an adhesion promoter the product HMDS which is heated to 150° C. for 60 seconds (see FIG. 7A). The resin is spread at a rate of 4,000 revs/minute for 30 seconds and for an acceleration of 1500 revs/min/s.

Then the resin-coated substrate is dried for 60 seconds at 115° C.

Lithography is then applied using a UV exposure beam 42 which passes through a mask 43 provided with n patterns defining the geometry of the micro-system tank (see FIG. 7B).

According to FIG. 7C, an on-track development (SHIPLEY® MF 319) is then applied for 60 seconds, then the substrate fitted with its resin is annealed at 115° C. for 2 minutes. Next, the pattern is subject to deoxidation of the pattern bottoms using a Nextral NE110 RIE device in an atmosphere of CHF₃/O₂ at a flow ratio of 50/10 standard cm³ per minute (50/10 sccm), at a pressure of 13.332 Pascal (100 mT), with 30 W of power, for one minute.

Next, in accordance with FIG. 7D, the areas unprotected by the resin are etched using a deep etch device of the DRIE ICP type. The blocking elements 45 are thus obtained. For the etching cycles, SF₆ is used and the following parameters: 129 standard cm³ per minute (129 sccm), 5.133 Pa (38.5 mT) and 600 W. For the passivation cycles, C₄F₈ is used and the following parameters: 85 standard cm³ per minute (85 sccm), 3.733 Pa (28 mT) and 600 W. It is specified that the ratio of etching times relative to passivation times is adjusted so as to obtain straight sides.

The next stage consists in scouring the resin mask using nitric acid HNO₃ giving off fumes under ultrasounds for five minutes.

The sides of the etch are then cleaned by oxidation in a tube furnace under oxygen for 50 minutes at 1,000° C. and then by chemical deoxidation using HF for a few seconds (FIG. 7E).

Thick oxidation 44 of the patterns is then applied over a thickness of 3 μm in a tube furnace under steam at 1000° C. for 18 hours and 50 minutes (FIG. 7F).

When using one of these micro-machining methods, it is also necessary to hollow out the fluid input means and the output means thereof in the micro-system. These fluid input and output means may be made in the tank and/or in the cap.

After this series of stages, we obtain a device similar to the one shown in FIG. 1, where the fluid input and output means have been hollowed out in the tank.

According to a variant not show, the input and output means may be in the cap, or equally well in the cap and in the tank.

We now need to start the second stage: the stage of implanting the beads into the micro-system.

The easiest access route for filling with micro-beads is over the blocking elements. This can be easily achieved by placing the micro-system to be filled at the bottom of a container. A certain quantity of micro-beads of a preset diameter is put in suspension in a liquid of known viscosity and density. The homogeneity of the solution can be increased if ultrasounds are used in order to avoid any micro-bead aggregate or again if surfactant is added to the solution. This solution is then poured into the container containing the device to be filled. The micro-beads in suspension deposit sediment and come to fill the free spaces or interstices between the blocking elements.

The minimum time at the end of which the device can be withdrawn from the suspension is related to Stokes law determining the sedimentation time of a sphere in a liquid medium according to the equation:

$${t}_{se dim entation} = \frac{9 n}{2 \times g \times {a}^{2} \times ( {ρ}_{1} - {ρ}_{2} )} \times d$$

with,

n: coefficient of viscosity of the liquid medium (g/cm.s),

d: maximum height of liquid (cm),

g: constant (cm/s²),

a: radius of the micro-spheres (cm),

ρ₁: density of the micro-spheres (g/cm³),

ρ₂: density of the liquid medium (g/cm³).

For example, the sedimentation time of a polystyrene bead of 5 micrometers in diameter and for a height of 1 cm is about four hours.

Lastly, it is necessary to prevent the beads from leaving the micro-system. To do this, the cap 7 is anchored hermetically to the tank 3 (see FIG. 1).

There are several ways of anchoring this cap. For example, the micro-reactor tank can be capped by a polydimethylsiloxane (PDMS) plate, comprising or not comprising input and/or output means, after said cap and said tank are treated by oxygen plasma, as described in the literature. In this case, PDMS is known to have properties of spontaneous adhesion to most solid media. In the case of a micro-reactor with a removable cap, the PDMS plate is simply pressed onto the tank, this being sufficient to obtain a good seal while preserving the possibility of reopening the micro-reactor subsequently after use by simply removing the PDMS plate. PDMS is mentioned as an example but other polymer materials are possible.

The micro-reactor tank can also be, for example capped by molecular sealing with a silica plate or a glass plate, comprising or not comprising input and/or output means, after the two hydroxylated substrates (SiO₂ substrate on silicon/glass or silica cap) have been cleaned and chemically prepared. The presence of silanol sites (SiOH) on the surface spontaneously attracts water molecules, and the two parts of the micro-component, namely the cap 7 and the tank 3, bond with one another by means of the water molecules. By heating, a part of the water contained between the two surfaces is eliminated until about three layers of water molecules are obtained which make adhesion possible.

Or else the micro-reactor tank can, for example, be capped by anodic sealing of a glass plate, comprising or not comprising input and/or output means.

Or else the micro-reactor tank can, for example, be capped by bonding a polymer plate selected by the user, comprising or not comprising input and/or output means, by using, for example an adhesive deposition by serigraphy process.

This type of bonding consists of three principal stages: serigraphy, which consists in applying the adhesive only to certain areas of the substrate, bonding which consists in bringing the substrate locally coated with adhesive and the cap into contact, and, finally heating which causes polymerisation of the adhesive. Polymerisation may be carried out photochemically if the adhesive can be polymerised under UV.

Lastly, the micro-reactor tank can, for example, be capped by direct silicon to silicon bonding (or SDB for Silicon Direct Bonding) to a silicon plate, comprising or not comprising input and/or output means.

According to the invention, it is also possible to make a multi-functional in volume micro-reactor by depositing, in the micro-system tank, micro-beads that have different functions. Indeed, on one and the same device, it is possible to incorporate micro-beads of different natures according to a number of methods.

The first method requires the use of functionalised beads of one and the same diameter but having different functions and involves masking the area not to be filled by sedimentation.

The second way of obtaining micro-beads that have different functions in one and the same micro-system can be achieved by placing the blocking elements in the tank with different gaps. The selectivity of the cavity areas that have different functions is then related to the diameter of the different micro-spheres comprising these functions. Filling by sedimentation must then always start with the largest micro-spheres.

An example of the result obtained can be seen in FIG. 6, where two diameters of beads 32a and 32b have been used and blocking elements 35 distributed so as to constitute wells.

### SOME APPLICATION EXAMPLES

The micro-reactor according to the invention can be used in a number of different applications in the field of chemical, electrochemical, biochemical or biological reactions.

The micro-reactor according to the invention can thus be used in the field of biochemistry, particularly, for example, in an enzymatic digestion reaction. To do this, micro-beads can be used, porous or non-porous, functionalised with trypsin, then introduced into the micro-system according to the invention. A fluid stream will then be allowed to flow in said micro-reactor in such a way that at least one constituent of said fluid stream reacts with the pre-functionalised beads able to produce a biological or biochemical reaction, and at the output(s) 9 of the micro-reactor a fluid stream is collected that includes the product(s) of said reaction.

The micro-reactor according to the invention can also be used in analysis.

For example, the bead-filled micro-system according to the invention can be used in separation chromatography. To this end micro-beads are used, porous or non-porous, supporting polar grafted phases (—CN, —NH2), which are introduced into the micro-system.

Micro-beads, porous or non-porous can also be used, supporting polar grafted phases, which are introduced into the micro-system to carry out ion exchange chromatography.

The bead-filled micro-system according to the invention can also be used in exclusion chromatography.

To this end, porous beads will be used with the diameters of the pores adapted to the degree of exclusion required.

The bead-filled micro-system according to the invention can also be used in affinity chromatography. Micro-beads will then be used, porous or non-porous supporting an effector with a biological affinity (enzyme-substrate, ligand-receptor, antigen-antibody) for a solute of a sample for analysis.

To carry out enzyme-substrate affinity chromatography, substrates or the like, reversible inhibitors, allosteric effectors or co-enzymes can in particular be used as effectors.

Or again, to carry out ligand-receptor affinity chromatography, haptens, antigens or antibodies will be used.

To carry out antigen-antibody affinity chromatography, hormones, peptides or peptidic analogues will be used for example.

The micro-reactor according to the invention may also be used in chemical reactions.

The micro-reactor in fact allows a system to be created that generates a perfect catalytic medium while allowing the ordering of porous micro-beads impregnated with catalyst. This geometric ordering of the micro-beads makes it possible, on the one hand, to increase very substantially the surface to volume ratio, and on the other hand, to obtain a homogeneous distribution of the flow within the reactor.

Moreover, the porous beads used can be a mixture of beads carrying different types of catalysts (for example: Pd, Pt, Rh etc.,).

The internal surface of the micro-reactor can itself be coated with a catalytic layer, particularly by chemical surface treatment, by sputtering or by co-evaporation.

A large number of catalytic liquid phase reactions can be transposed in a micro-reactor, such as for example the Suzuki coupling reaction:

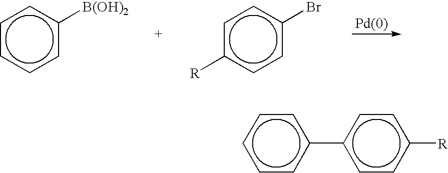

We may also mention the coupling between 4-bromobenzonitrile and phenylboronic acid, which can be achieved under an electro-osmotic flow:

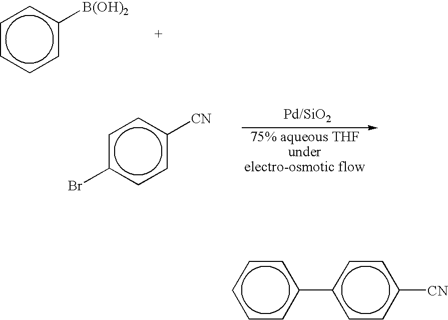

The efficiency of the micro-reactor in relation to the increase in reactive yields on the microscopic scale has been demonstrated in the document [5].

### REFERENCES

[1] R. D. OLESCHUK, L. L. SHULTZ-LOCKYEAR, Y. NING, D. J. HARRISON, Analytical Chemistry 72, 585-590 (2000).

[2] C. WANG, R. OLESCHUK, F. OUCHEN, J. LI, P. THIBAULT, D.J.HARRISON, Rapid Communications in Mass Spectrometry 14, 1377-1383 (2000).

[3] H. ANDERSSON, W. van der WIJNGAART, P. ENOKSSON, G. STEMME, Sensors and Actuators B 67, 203-208 (2000).

[4] H. ANDERSSON, C. JONSSON, C. MOBERG, G. STEMME, Micro Total Analysis Systems, J. M. RAMSEY and Van den BERG (eds.), (Kluwer academic Publishers, 2001).

[5] G. M. GREENWAY, S. J. HASWELL, D. O. MORGAN, V. SKELTON and P. STYRING, Sensors & Actuators B 63, 153 (2000).

1. A micro-system for receiving beads and obtaining a precise positioning of said beads at preset locations in said micro-system, comprising:
a tank that has a cavity which is fitted with blocking elements having the form of columns, said blocking elements allowing to block beads in interstices between said blocking elements in an ordered way and in stacks, said interstices constituting said preset locations,
a cap hermetically sealing said tank,
and import means and output means allowing a fluid to flow in said cavity.

2. The micro-system according to claim 1, wherein said blocking elements are integral with the bottom of said cavity or said cap.

3. The micro-system according to claim 1, wherein said beads all have the same diameter, and said blocking elements are evenly arranged in a two-dimensional network.

4. The micro-system according to claim 1, wherein said micro-system having to receive beads of different diameters, said blocking elements are distributed so as to obtain a positioning of said beads as a function of their diameters.

5. The micro-system according to claim 4, wherein said blocking elements are distributed so as to constitute wells intended to receive beads of a first preset diameter and spaces between the wells intended to receive beads of a second preset diameter.

6. The micro-system according to claim 3, wherein said two-dimensional network is a hexagonal mesh.

7. The micro-system according to claim 3, wherein said two-dimensional network is a square mesh.

8. The micro-system according to claim 1, wherein said blocking elements have a transverse cross-section of a shape selected from among discs, ellipses and polygons.

9. The micro-system according to claim 8, wherein said blocking elements have a transverse cross-section in the shape of a hexagon.

10. The micro-system according to claim 1, wherein said blocking elements are of a height that allows at least two beads to be stacked.

11. A micro-reactor comprising the micro-system according to claim 1 and beads of one and the same diameter and with the same function, fitted between said blocking elements.

12. A micro-reactor comprising the micro-system according to claim 1 and beads, of the same diameter but functionalised differently, fitted between said blocking elements.

13. A micro-reactor comprising the micro-system according to claim 1 and beads, with the same function but of different diameters, fitted between said blocking elements.

14. A micro-reactor comprising the micro-system according to claim 1 and beads, of different diameters and functions, fitted between said blocking elements.

15. A process for making the micro-system according to claim 1, comprising the following stages:
forming, by micro-machining a substrate, the tank that has said cavity fitted with said blocking elements,
supplying a cap intended to seal said cavity of said tank hermetically, and
forming said fluid import means and said output means by micro-machining said tank and/or said cap.

16. The process according to claim 15, wherein said micro-machining is carried out by a process of dry or wet etching a material.

17. The process according to claim 15, wherein said micro-machining is carried out by impression moulding process.

18. The process according to claim 15, wherein said micro-machining is carried out by photolithography process.

19. A process for obtaining the micro-reactor according to claim 11, comprising filling functionalised beads in suspension in a liquid by sedimentation.

20. A process for obtaining a multi-functional micro-reactor, comprising filling the micro-system according to claim 3 with functionalised beads of one and the same diameter but with different functions, comprising:
for beads functionalised according to a first function, the following stages:
a) placing a cover on said tank leaving accessible the part in which it is wished to place the beads of a first function,
b) filling by sedimentation, and
c) withdrawing said cover,
for beads functionalised according to another function, the repetition, as many times as there are functions remaining, of stages a) to c) with beads of said other function,
sealing said tank with said cap.

21. A process for obtaining a multi-functional micro-reactor by filling the micro-system, according to claim 4, with beads the function of which is related to the diameter of said beads, comprising at least two filling stages, the order of said filling stages corresponding to the decreasing order of the diameter of said beads.

22. A process for implementing a biochemical or biological reaction, comprising flowing a fluid stream in the micro-reactor according to claim 11, so that at least one constituent of said fluid stream reacts with pre-functionalised beads able to produce a chemical, electrochemical, biological or biochemical reaction, and at micro-reactor output(s) a fluid stream is collected that includes product(s) of said reaction.

23. The process according to claim 22, wherein said reaction is a reaction of the substrate enzyme type, said pre-functionalised beads able to produce a biological or biochemical reaction are enzymes, said constituent of the fluid stream is a substrate of the enzyme, and said products of the reaction are products arising from reaction of said enzyme with said substrate.

24. The process according to claim 22, wherein said reaction is an enzymatic digestion reaction by a protease, said pre-functionalised beads able to produce a biological or biochemical reaction are proteases and said constituents of the fluid stream are peptides or proteins and said products of the reaction are peptidic segments.

25. The process according to claim 24, wherein the enzyme is trypsin.
